(19) United States
(12) Patent Application Publication
(10) Pub. No.: US 2009/0258565 A1
(43) Pub. Date: Oct. 15, 2009

(54) Method for Manufacturing Display Panel within Substrates having Different Thickness

(75) Inventors: Jong-Wen Chwu, Hsin-Chu (TW); Yu-Chen Liu, Hsin-Chu (TW); Shu-Chih Wang, Hsin-Chu (TW); Chao-Cheng Lin, Hsin-Chu (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: AU OPTRONICS CORPORATION, Hsin-Chu (TW)

(21) Appl. No.: 12/403,652

(22) Filed: Mar. 13, 2009

(30) Foreign Application Priority Data
Apr. 11, 2008 (TW) 97113138

(51) Int. Cl. H01J 9/26; H01J 9/00; B44C 1/22

(52) U.S. Cl. 445/25; 445/24; 216/13

(57) ABSTRACT

The present invention provides a method for manufacturing display panel with substrates having different thickness. The display panel manufacturing method includes assembling a first substrate and a second substrate, positioning the anti-etching layer on the outer surface of the first substrate and etching the substrates at the first etching process. Because the anti-etching layer is disposed on the first substrate, the first substrate is protected by the anti-etching layer from being etched or later etched. Simultaneously, the second substrate is etched to reduce its thickness in order to adjust the thickness difference between the first substrate and the second substrate.

This application claims the priority based on a Taiwanese Patent Application No. 097113138, filed on Apr. 11, 2008, the disclosure of which is incorporated herein by reference in its entirety.

### BACKGROUND OF THE INVENTION

1. Field of the Invention

The present invention relates generally to a method for manufacturing a display panel. Particularly, the present invention relates to a method for manufacturing a display panel having substrates with diverse thickness.

2. Description of the Prior Art

With the surging demand of the thin display monitor, it has become more and more important to develop new technique for attenuating the display panel. The technique for attenuation purpose basically includes two major processes: grinding the substrates by physical method; and etching the substrates by chemical method. For the chemical etching method, it has become well-established for the past years. For example, the main factor for evaluating the quality of the Organic Light Emitting Display (OLED) panels is based on the total thickness and the relative thickness difference between substrates. Therefore, in the display panel industry, engineers are urged to develop new methods for effectively and flexibly adjusting the total thickness and the relative thickness difference between substrates.

In current process, both outer surfaces of the display panel are simultaneously etched during chemical etching method. Thus, while the display panel is usually composed of two substrates, it is impossible to flexibly adjust the thickness difference between the first substrate and the second substrate by traditional chemical etching method. Consequently, the grinding method has to be applied, if the thickness difference of the substrates is required to be alternated. However, when the physical grinding method is involved, it usually generates scratches on the substrates. In addition, the augment of the budget cost and the uncertainty of the display panel process also need to be taken into consideration. Therefore, it has become a research goal that how to manufacture the display panel having different substrate thickness without using physical grinding process.

### SUMMARY OF THE INVENTION

One of the objectives of the present invention provides a method for manufacturing a display panel, which is capable of generating a display panel having different substrate thickness.

The display panel manufacturing method of the present invention includes assembling a first substrate and a second substrate; positioning an anti-etching layer on the outer surface of the first substrate; and etching both of the surfaces of the substrates at the first etching process.

### BRIEF DESCRIPTION OF THE DRAWINGS

FIG. 1 shows a flow chart of an embodiment of a display panel manufacturing method of the present invention.

FIG. 2A illustrates an embodiment of substrates assembling step.

FIG. 2B shows an embodiment of the anti-etching layer positioning step.

FIG. 2C shows an embodiment of the first etching step of the present invention.

FIG. 3 illustrates another flow chart of the display panel manufacturing method of the present invention.

FIG. 4A illustrates an embodiment of the anti-etching layer positioning process step of the present invention.

FIG. 4B illustrates another embodiment of the anti-etching layer positioning process step of the present invention.

FIG. 4C illustrates an embodiment of the first etching process of the present invention.

FIG. 4D shows another embodiment of the first etching process of the present invention.

FIG. 5 shows a flow chart of another embodiment of the display panel manufacturing method of the present invention.

FIG. 6A shows an embodiment of the initiating etching step of the present invention.

FIG. 6B shows an embodiment of the anti-etching layer positioning step of the present invention.

FIG. 6C illustrates another embodiment of the anti-etching layer positioning step of the present invention.

FIG. 6D shows an embodiment of the first etching process of the present invention.

FIG. 6E illustrates another embodiment of the first etching process of the present invention.

FIG. 7 shows a flow chart of another embodiment of the display panel manufacturing method.

FIG. 8 illustrates an embodiment of the second etching process of the present invention.

### DETAILED DESCRIPTION OF THE PREFERRED EMBODIMENT

The present invention provides a display panel manufacturing method and a display panel having different thickness thereof. In an embodiment, the display panel of the present invention can be, but not restrained to, a LCD display panel. However, in another embodiment, the display panel of the present invention may include a Polymer Light Emitting Diode (PLED) display panel. Besides, the display panel of the present invention can be applied to a variety of display panels including panel monitors, domestic flat televisions, personal computers and laptops, or monitors of cell-phones and digital cameras.

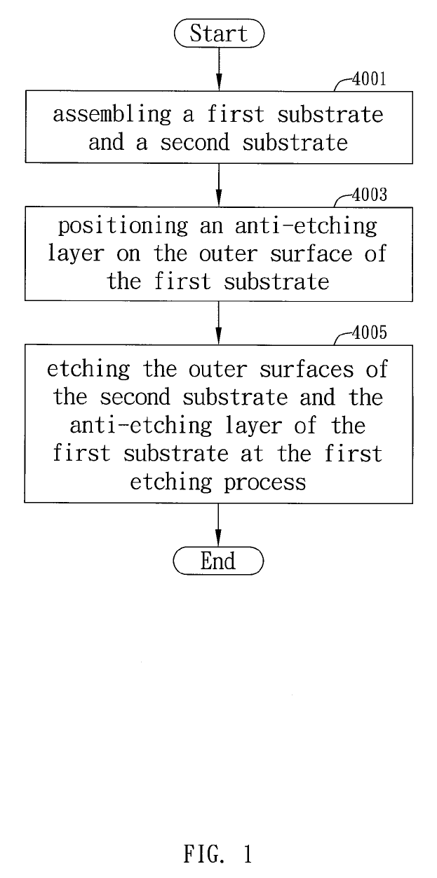

As FIG. 1 shows a flow chart of an embodiment of a display panel manufacturing method of the present invention. The method includes: step 4001, assembling a first substrate and a second substrate; step 4003, positioning an anti-etching layer on the outer surface of the first substrate; and step 4005, etching both of the outer surfaces of the substrates at a first etching process. The details of each step will be described as followings.

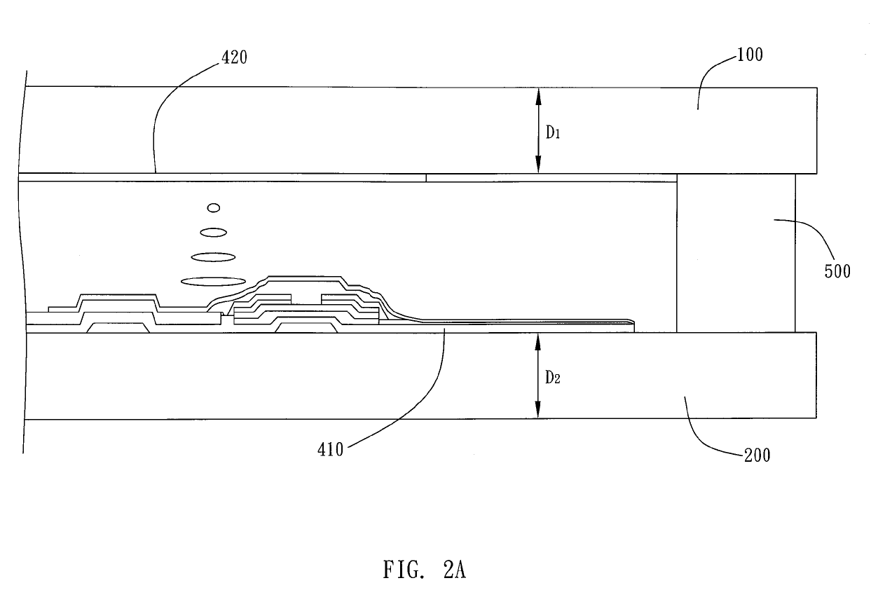

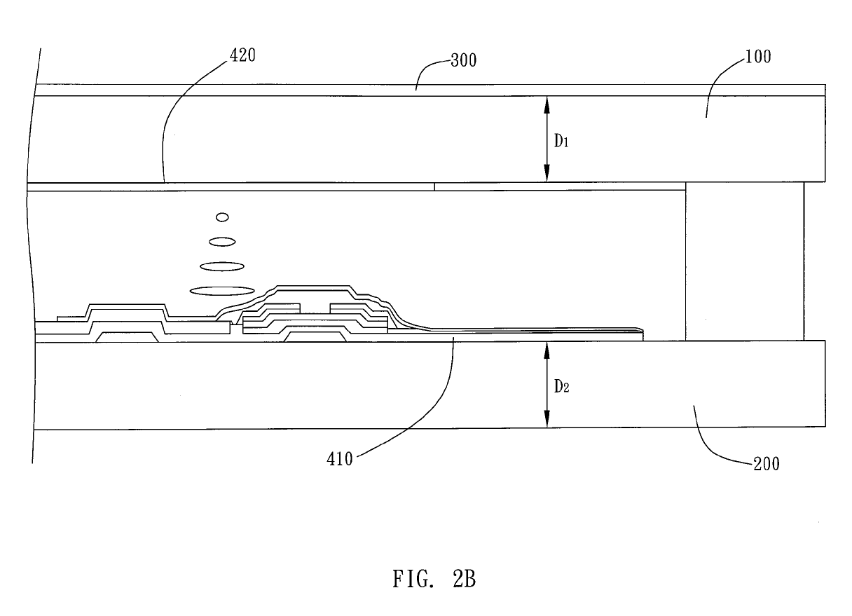

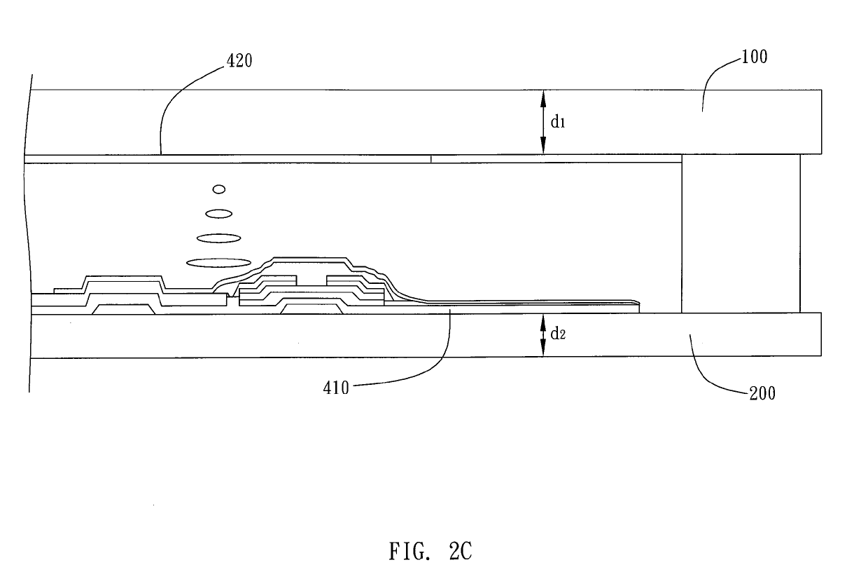

In the embodiment shown in FIG. 2A, the display panel includes a first substrate 100, a second substrate 200, a driving circuit layer 410 and a light-filtering layer 420. In the embodiment, the driving circuit layer 410 is disposed on the inner surface of the second substrate 200, while the light-filtering layer 420 is disposed on the inner surface of the first substrate 100. In this embodiment, the material of the first substrate 100 and the second substrate 200 preferably includes glass; however, in other embodiments, the substrate material is selected from the group consisting of polyethylene terephthalate (PET), poly-methylmethacrylate (PMMA), polycarbonate (PC), polystyrene (PS), a combination thereof and other suitable transparent materials. Preferably, the material of the first substrate 100 is the same as the material of the second substrate 200. However, in other embodiments, the first substrate 100 and the second substrate 200 can have different materials.

As shown in FIG. 2A, the light-filtering layer 420 is a color filter. In this embodiment, driving circuit layer 410 is a thin-film transistor (TFT) layer. However, in another embodiment, the driving circuit layer 410 can be a Metal Insulator Metal-TFD (MTM-TFD) circuit layer and other functional circuit layers. Particularly, the manufacturing process of the TFT layer preferably includes the amorphous silicon (a-Si) processes, low temperature poly-silicon (LTPS) process and other suitable processes.

Referring to FIG. 1, FIG. 2A, FIG. 2B, and FIG. 2C, FIG. 1 shows the flow chart of the preferred embodiment of the present invention. FIG. 2A presents an embodiment of the substrates assembling step, while FIG. 2B demonstrates an embodiment of the anti-etching layer positioning process step. FIG. 2C shows an embodiment of the first etching process of the present invention. Particularly, in the substrates assembling step 4001, assembling the first substrate 100 and the second substrate 200 further includes sealing a lateral interstice between the first substrate 100 and the second substrate 200. In this embodiment, the lateral interstice is preferably sealed by a sealant 500, which includes UV sealants. In other words, the step 4001 is implemented by using the UV sealant to seal the lateral interstice between the first substrate 100 and the second substrate 200. However, in other embodiments, the step of assembling the first substrate 100 and the second substrate 200 can be performed by other processes. In the embodiment, an initial thickness difference (|D2−D1|≧0, D1 is the thickness of the first substrate 100; D2 is the thickness of the second substrate 200) exists between the first substrate 100 and the second substrate 200. In other words, the initial thickness of the first substrate 100 can be different from or the same as the initial thickness of the second substrate 200.

In the embodiment shown in FIG. 2B, the anti-etching layer 300 is disposed on the outer surface of the first substrate 100. The material of the anti-etching layer 300 is preferably selected from the group consisting of wax, silicon nitride and other suitable anti-etching materials. In this embodiment, the anti-etching layer 300 can be a completely anti-etching material or one kinds of partial anti-etching material. In other words, the anti-etching layer 300 of the completely anti-etching material is substantially not etched away, but the anti-etching layer 300 of partially anti-etching material will be etched away at an etching rate during the first etching process. Furthermore, the anti-etching layer 300 can be disposed on the outer surface of the first substrate 100 by chemical vapor deposition process, pasting process, coating process, spraying process or other suitable processes. With reference to FIG. 2B, when the light-filtering layer 420 is disposed on the inner surface of the first substrate 100, the first substrate 100 is presented as a light-filtering substrate. In this embodiment, the anti-etching layer 300 is disposed on the outer surface of the light-filtering substrate. If a completely anti-etching material is used as the anti-etching layer 300, the outer surface of the first substrate 100 will not be etched during the first etching process. However, in another embodiment, the anti-etching layer 300 is alternatively disposed on the second substrate 200. That is the anti-etching layer 300 is attached on the outer surface of the substrate having the driving circuit layer, ie the driving circuit substrate. Besides, according to different applications, the anti-etching layer 300 can be disposed on both of the outer surfaces of the light-filtering substrate and the driving circuit substrate.

In the first etching process step 4005, the second substrate 200 and the first substrate 100 having the anti-etching layer 300 are etched. In this embodiment, the chemical etchant include an etchant containing fluorine, such as hydrofluoric acid, ammonium fluoride and so on. Because the anti-etching layer 300 is disposed on the outer surface of the first substrate 100, the first substrate 100 is protected by the anti-etching layer 300 from being etched or etched at a relatively lower ratio, while the thickness of the substrate 200 lack of the anti etching layer 300 is significantly reduced during the first etching process. In the first embodiment shown in FIG. 2C, after the step 4005, the anti-etching layer 300 of the partially anti-etching material is completely removed and the first substrate 100 is partially etched to reduce the thickness (D1) to thickness (d1). At the same time, the thickness (D2) of the second substrate 200 is reduced to the thickness (d2) during the first etching process. Thus, the initial thickness difference (|D2−D1|≧0) between the first substrate 100 and the second substrate 200 is alternated to the first thickness difference (|d2−d1|≧1). In this embodiment, the first thickness difference can be zero or not zero, but should be different from the initial thickness difference (|d2−d1|≠|D2−D1|). However, in other embodiments, the anti-etching layer 300 can protect the first substrate 100 from being substantially etched to maintain its original thickness, D1.

In an embodiment, the anti-etching layer 300 is composed of silicon nitride which is a partially anti-etching material with respect to the glass substrate during the first etching process. Therefore, the thickness of anti-etching layer 300 will be reduced during the etching process. In order to control the thickness difference between the initial thickness difference and the first thickness difference, the anti-etching layer positioning process step 4003 further includes determining the thickness of the anti-etching layer 300 to change the difference between the first thickness difference and the initial thickness difference (|d2−d1|−|D2−D1|). In other embodiments, while the anti-etching layer 300 can sustain for a longer etching time period to increase the thickness thereof. In other words, by increasing the thickness of the anti-etching layer 300 to provide the first substrate 100 with a better protection, the difference between the first thickness difference and the initial thickness difference can be augmented.

As the anti-etching layer 300 is composed of the partially anti-etching material, the anti-etching layer 300 has an etching ratio with respect to the first substrate 100 and the second substrate 200. In an embodiment, the etching ratio (or the selectivity) means the removing rate of the anti-etching layer 300 etched by hydrofluoric acid to the removing rate of the glass. In this embodiment, by using the etchant containing fluorine at the first etching process, the etching rate of the glass preferably ranges between 0.5 μm/min. and 20 μm/min. In order to adjust the difference between the first thickness difference and the initial thickness difference, the anti-etching layer positioning process step 4003 further includes determining the material of the anti-etching layer 300 to adjust the etching rate for changing a time point of removing all of the anti-etching layer 300 and then implementing the etching process on the first substrate 100. Taking the anti-etching layer 300 of silicon nitride for an example, the etching rate of the silicon nitride by hydrofluoric acid can be adjusted from 0.16% to 50%. In the embodiment shown in FIG. 2C, after the first etching process step 4005, the first substrate 100 and the second substrate 200 have a first thickness difference (|d2−d1|>0), while the anti-etching layer 300 is completely removed during the first etching process. However, the material of the anti-etching layer 300 will also affect the difference between the initial thickness difference and the first thickness difference. For instance, by utilizing the material of less etching rate, the first thickness difference between substrates will be increased. However, in another embodiment, after the first etching process, the anti-etching layer 300 may be remained for subsequent processes.

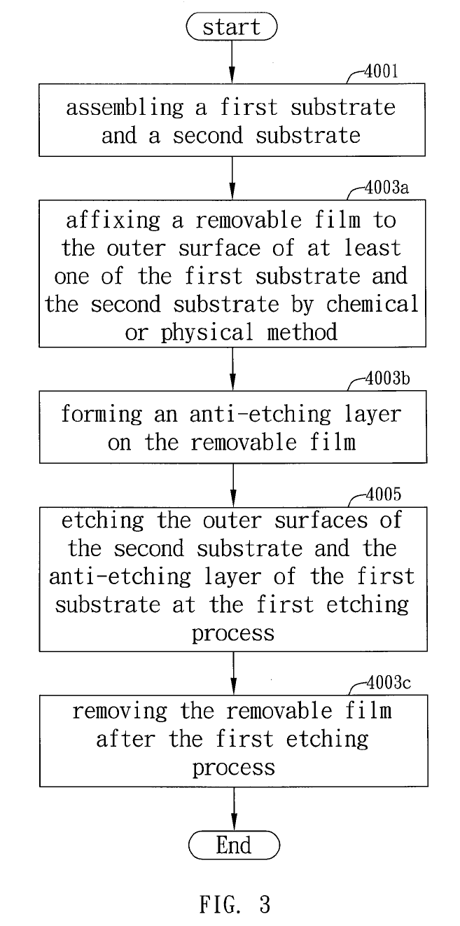

A flow chart of another embodiment of the present invention is shown in FIG. 3. In this embodiment, the step 4003 further includes step 4003a, step 4003b and step 4003c. Step 4003a includes affixing a removable film to the outer surface of at least one of the first substrate and the second substrate by chemical or physical method. Step 4003b includes forming the anti-etching layer on the removable film. Furthermore, step 4003c includes discarding or removing the removable film after the first etching process. Step 4003a preferably includes affixing the removable film to the outer surface of at least one of the first substrate and the second substrate by electrostatic attraction. The detail of each step is described below.

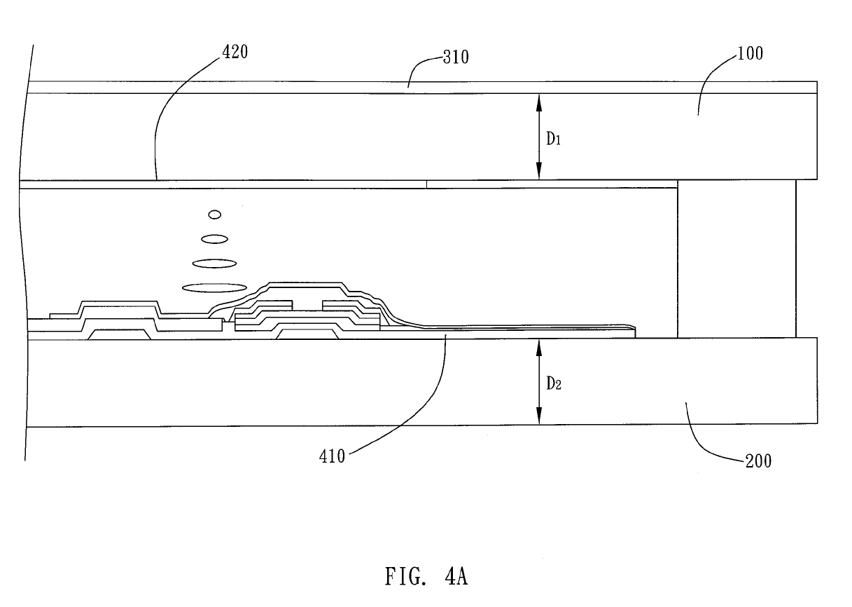

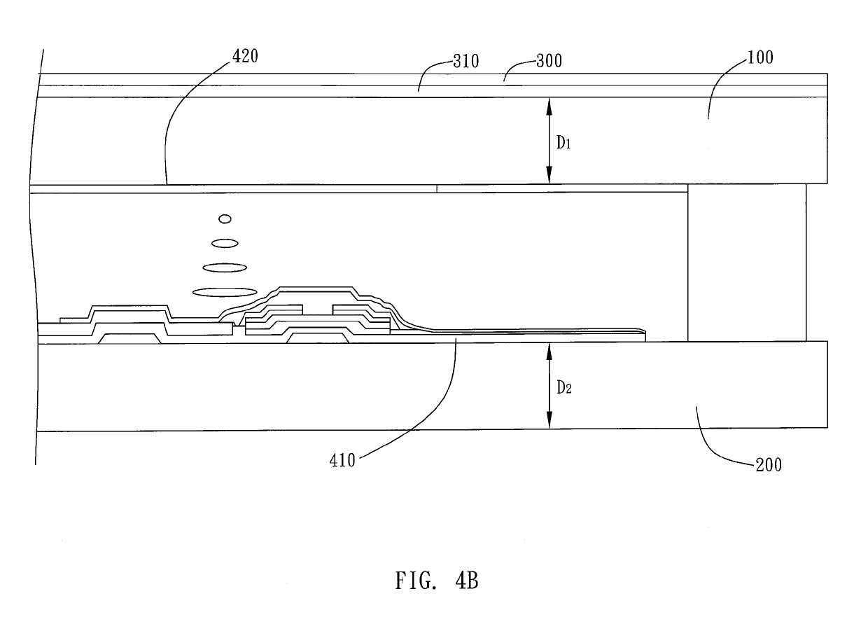

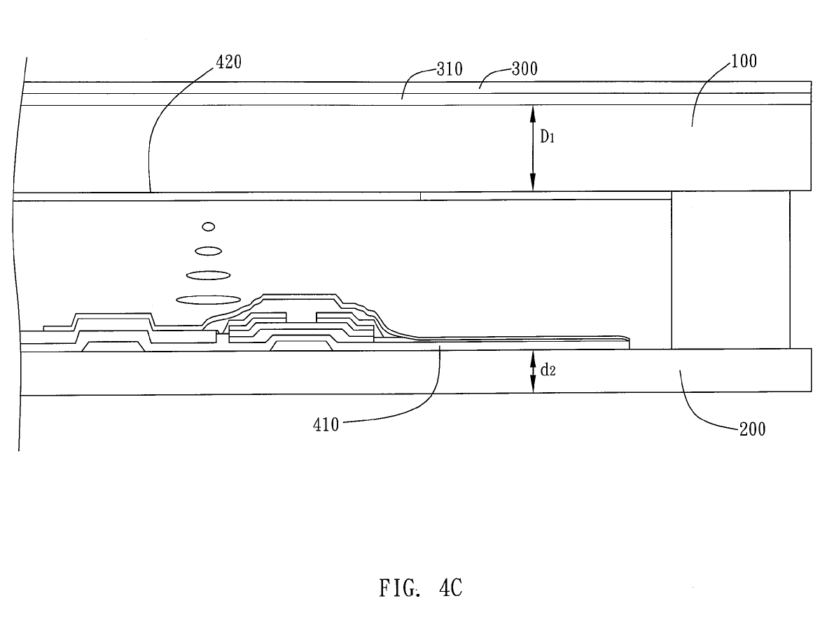

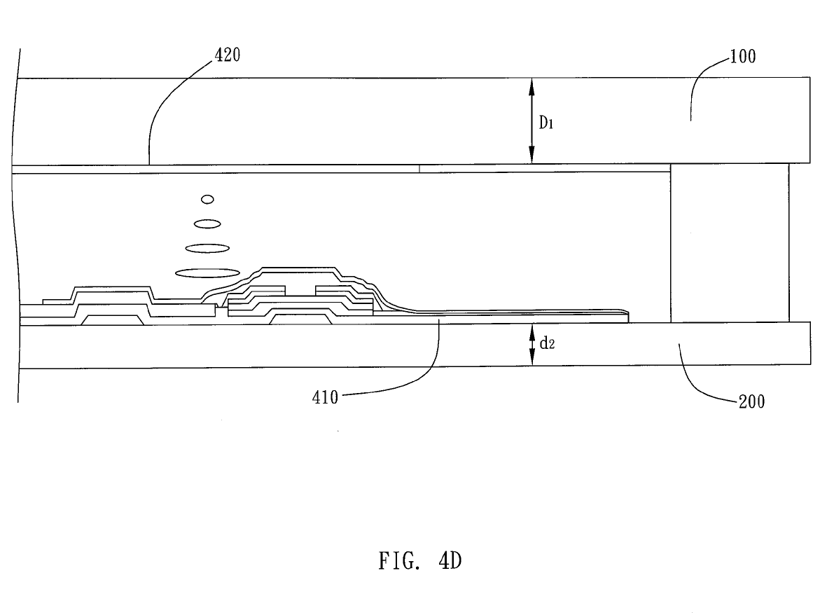

In an embodiment shown in FIG. 4A, the removable film 310 is disposed, by electrostatic attraction, on the outer surface of the first substrate 100 (its thickness is D1). However, in another embodiment, the removable film 310 can be affixed to the outer surface of at least one of the first substrate 100 and the second substrate 200 (its thickness is D2) by chemical or physical method. In an embodiment, the removable film 310 is composed of plastics, such as polycarbonate (PC). In the second embodiment shown in FIG. 4B, an anti-etching layer 300 is formed on the removable film 310. In this embodiment, the material of the anti-etching layer 300 is preferably selected from the group consisting of wax and silicon nitride. In another embodiment, by using the wax as the anti-etching layer 300 after the first etching process, the anti-etching layer 300 is usually remained and the thickness of the protected substrate (eg. light-filtering substrate or electrode component substrate) remain unchanged. In other words, the initial thickness of the substrate having the wax as the anti-etching layer 300 is consistent with the thickness thereof after the first etching process.

In the embodiment shown in FIG. 4C, after the first etching process, a first thickness difference exists between the first substrate 100 and the second substrate 200 (|d2−D1|). Because of the anti-etching layer 300, the initial thickness of the first substrate 100 remains unchanged after the etching process. Accordingly the first thickness difference is different from the initial thickness difference (|d2−D1|≠|D2−D1|). In other words, the anti-etching layer 300 determines whether the protected substrate will be etched so as to affect the thickness difference as described above. With reference to FIG. 4D, after the first etching process, the removable film 310 and the anti-etching layer 300 are removed. Because the anti-etching layer 300 is formed on the removable film 310, when the removable film 310 is removed from the first substrate 100 or the second substrate 200, the anti-etching layer 300 is removed together with the removable film 310. In an embodiment, the removable film 310 can be manually or automatically removed from the first substrate 100 or the second substrate 200 by tearing or washing.

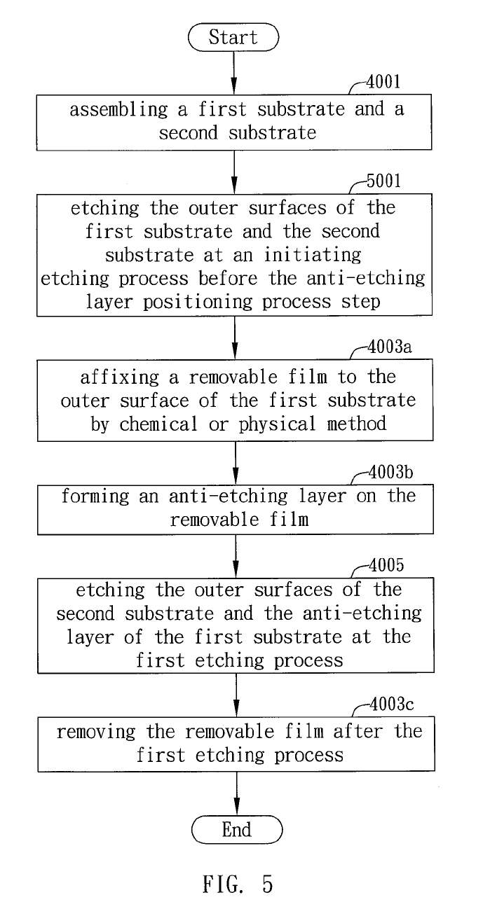

A flow chart of another embodiment of the present invention is shown in FIG. 5. The display panel manufacturing method of the present invention further includes a step 5001. Step 5001 is performed before the anti-etching layer positioning process step. In step 5001, an initiating etching process to etch the outer surfaces of the first substrate 100 and the second substrate 200. Step 4003 includes step 4003a, step 4003b and step 4003c. Step 4003a includes affixing the removable film on the outer surfaces of at least of one of the first substrate and the second substrate by chemical or physical method. Step 4003b includes forming the anti-etching layer on the removable film. Finally, the step 4003c includes removing or discarding the removable film after the first etching process.

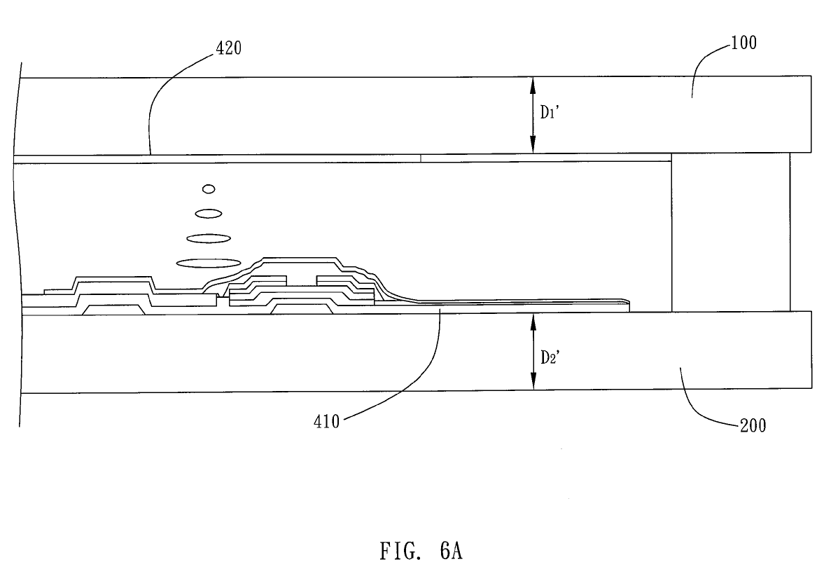

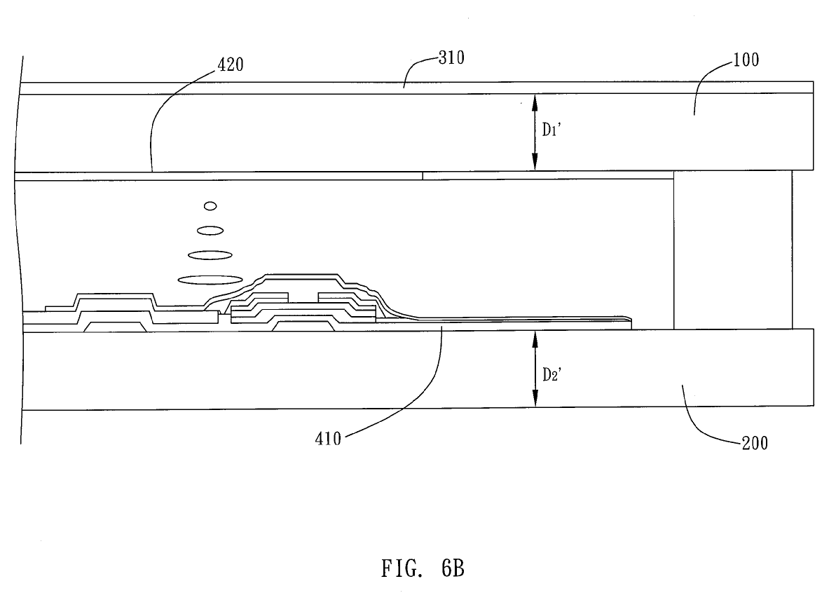

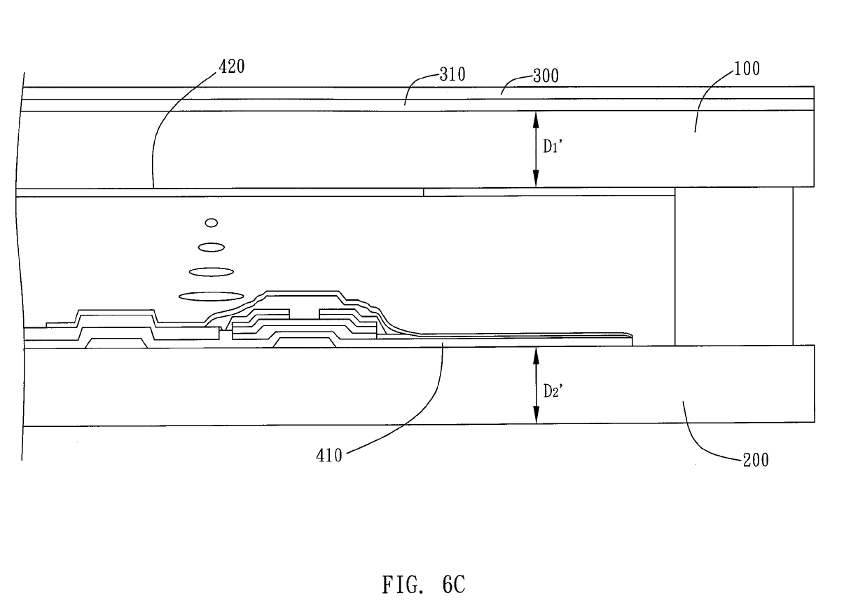

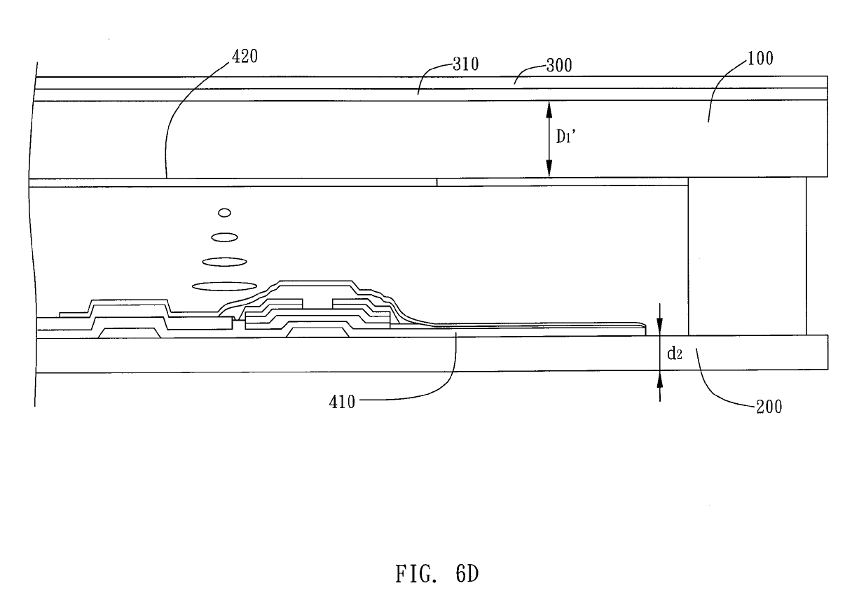

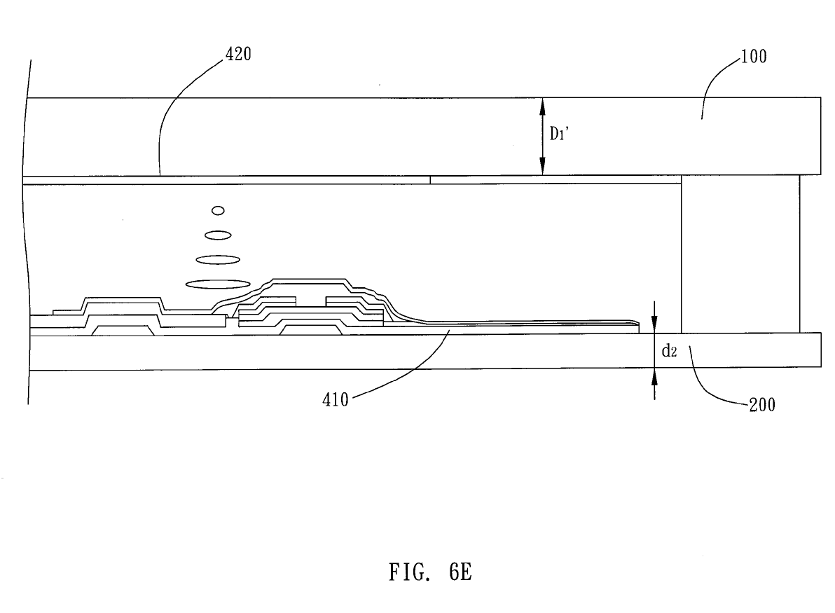

In an embodiment shown in FIG. 6A, first of all, in step 5001, the initiating etching process step is performed to etch the first substrate 100 and the second substrate 200 without any anti-etching layer 300 thereon to reduce both of their initial thicknesses (from D1 to D1′ and from D2 to D2′). In the embodiment, after the initiating etching process, the thickness difference existing between these substrates is the same as the initial thickness difference (|D2−D1|=|D2′−D1′). However, in other embodiments, while the material of the first substrate 100 is different from the material of the second substrate 200, the thickness difference between both of the substrates will be different after the initiating etching process (|D2−D1|≠|D2′−D1′|). With reference to FIG. 6B, the removable film affixing step 4003a preferably includes affixing an removable film 310 to the outer surface of the first substrate 100 by electrostatic attraction. With reference to FIG. 6C, the anti-etching layer forming step 4003b includes positioning an anti-etching layer 300 on the removable film 310. With reference to FIG. 6D, after the first etching process step 4005, a first thickness difference (|d2−D1′|) exists between the first substrate 100 and the second substrate 200. Because of the anti-etching layer 300, the thickness of the first substrate 100 remain unchanged, so that the first thickness difference is different from the initial thickness difference (|D2−D1|=|D2′−D1′|≠|d2−D1′|). With reference to FIG. 6E, after the first etching process, the removable film removing step 4003c is performed to remove the remaining anti-etching layer 300 and the removable film 310.

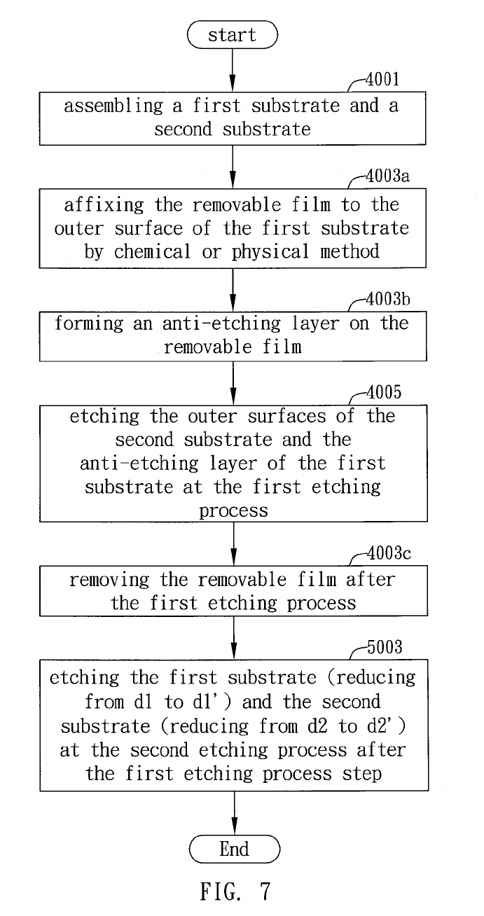

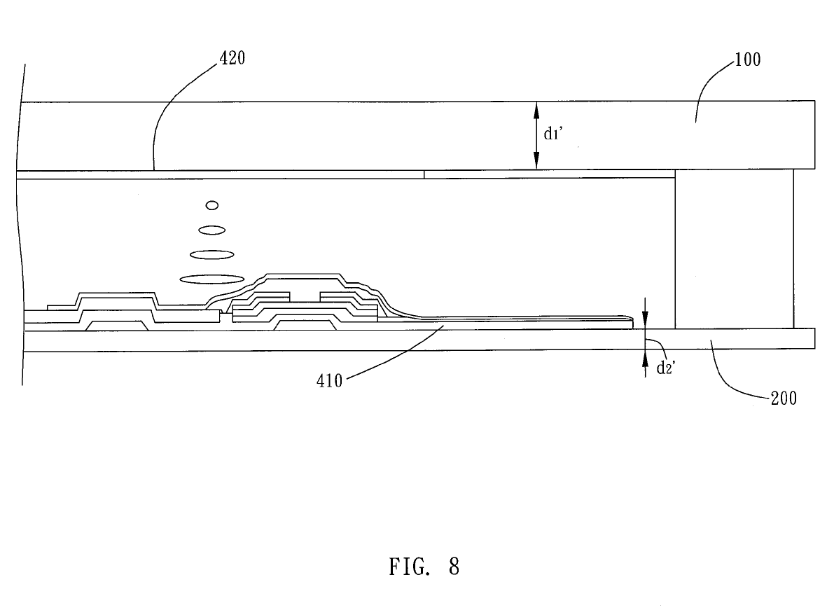

A flow chart of another embodiment of the present invention is shown in FIG. 7. The display panel manufacturing method of the present invention further includes step 5003. Step 5003 includes a second etching process to etch the first substrate (to reduce thickness from D1 to d1) and the second substrate (from D2 to d2) after the first etching process step 4005. In this embodiment, the etchant used preferably include an etchant containing fluorine, such as hydrofluoric acid, ammonium fluoride and so on. In this embodiment, after removing the anti-etching layer 300 and the removable film 310, the second etching process step 5003 is performed to etch the outer surfaces of the first substrate 100 and the second substrate 200. With the reference to FIG. 8, because the outer surfaces of the first substrate 100 or the second substrate 200 is no longer protected by the anti-etching layer, both of the substrates will be etched to reduce their thicknesses. Thus, the thickness of the first substrate 100 will be reduced from thickness d1 to d1′, while the thickness of the second substrate 200 is reduced from thickness d2 to d2′. In the preferred embodiment, the difference between the second thickness difference and the first thickness difference is zero (|d2−d1|−|d2′−d1′|=0). In other words, the second etching process also reduces the thickness difference between the first substrate 100 and second substrate 200. Thus, the second etching process does not affect the final thickness difference between the substrates but provides the effect of adjusting the total thickness of the display panel substrates. In another embodiment, while the material of the first substrate 100 is different from the material of the second substrate 200, the second etching process may distinctly reduce the thicknesses to affect the final thickness difference.

Although the preferred embodiments of the present invention have been described herein, the above description is merely illustrative. Further modification of the invention herein disclosed will occur to those skilled in the respective arts and all such modifications are deemed to be within the scope of the invention as defined by the appended claims.

What is claimed is:

1. A display panel manufacturing method, comprising:
assembling a first substrate and a second substrate;
positioning an anti-etching layer on an outer surface of the first substrates; and
etching the assembled substrates at a first etching process.

2. The display panel manufacturing method of claim 1, wherein the anti-etching layer positioning process is selected from the group consisting of chemical vapor deposition process, pasting process, coating process and spraying process.

3. The display panel manufacturing method of claim 2, wherein a material of the anti-etching layer is selected form the group consisting of wax and silicon nitride.

4. The display panel manufacturing method of claim 1, wherein an initial thickness difference between the first substrate and the second substrate before the first etching process is not less than zero thickness, while a first thickness difference between the first substrate and the second substrate, after the first etching process, is different from the initial thickness difference.

5. The display panel manufacturing method of claim 4, wherein the anti-etching layer positioning process further includes determining a thickness of the anti-etching layer to change the difference between the first thickness difference and the initial thickness difference.

6. The display panel manufacturing method of claim 1, wherein the anti-etching layer has an etching rate with respect to the first substrate and the second substrate, the anti-etching layer positioning process includes determining a material of the anti-etching layer to adjust the etching rate.

7. The display panel manufacturing method of claim 6, wherein the etching rate is between 0.5 μm/min and 20 μm/min.

8. The display panel manufacturing method of claim 1, wherein the anti-etching layer positioning process includes:
affixing a removable film to the outer surface of the first substrate by chemical or physical method; and
forming the anti-etching layer on the removable film, wherein the removable film is removed after the first etching process.

9. The display panel manufacturing method of claim 8, wherein the removable film affixing step includes affixing the removable film to the outer surface of the first substrate by electrostatic attraction.

10. The display panel manufacturing method of claim 1, further comprising performing a pretreatment process to etch the outer surfaces of the first substrate and the second substrate before the anti-etching layer positioning process.

11. The display panel manufacturing method of claim 10, wherein the pretreatment process, the first etching process or the second etching process is performed by using an etchant containing fluorine.

12. The display panel manufacturing method of claim 1, further comprising performing a second etching process to etch the outer surfaces of the first substrate and the second substrate after the first etching process.

13. The display panel manufacturing method of claim 12, wherein the pretreatment process, the first etching process or the second etching process is performed by using an etchant containing fluorine.

14. The display panel manufacturing method of claim 1, wherein the substrates assembling step further includes sealing a lateral interstice between the first substrate and the second substrate.

15. A display panel manufacturing method, comprising:
assembling a first substrate and a second substrate, wherein an initial thickness difference between the first substrate and the second substrate is not less than zero thickness;
positioning an anti-etching layer on an outer surface of the first substrate; and
etching an outer surface of the second substrate and the anti-etching layer disposed on the first substrate at a first etching process to generate a first thickness difference between the first substrate and the second substrate, while the first thickness difference is different from the initial thickness difference.

16. The display panel manufacturing method of claim 15, further comprising etching the outer surfaces of the first substrate and the second substrate at a second etching process.

17. The display panel manufacturing method of claim 15, wherein the anti-etching layer positioning process further includes determining a thickness of the anti-etching layer to change a difference between the first thickness difference and the initial thickness difference.

18. The display panel manufacturing method of claim 15, wherein the anti-etching layer with respect to the first substrate and the second substrate has an etching rate, the anti-etching layer positioning process includes determining a material of the anti-etching layer to adjust the etching rate for changing a difference between the first thickness difference and the initial thickness difference.

19. The display panel manufacturing method of claim 16, wherein the first etching process or the second etching process is performed by using an etchant containing fluorine.

20. The display panel manufacturing method of claim 15, wherein the anti-etching layer positioning process includes:
affixing a removable film to the outer surfaces of the first substrate by chemical or physical method;
forming the anti-etching layer on the removable film, wherein the removable film is removed after the first etching process.

21. The display panel manufacturing method of claim 16, wherein the second etching process is a pretreatment process to etch the outer surfaces of the first substrate and the second substrate before the anti-etching layer positioning process.

22. The display panel manufacturing method of claim 15, wherein the substrates assembling step further includes sealing a lateral interstice between the first substrate and the second substrate.
